(19) United States
(12) Patent Application Publication
(10) Pub. No.: US 2018/0197571 A1
(43) Pub. Date: Jul. 12, 2018

(54) TRANSLATING LAYER FOR COMBINING FCC AND HCP LATTICE STRUCTURES

(71) Applicant: Seagate Technology LLC, Cupertino, CA (US)

(72) Inventor: Jan-Ulrich THIELE, Sunnyvale, CA (US)

(21) Appl. No.: 15/403,123

(22) Filed: Jan. 10, 2017

(51) Int. Cl. G11B 5/738; C30B 23/08; C30B 23/02; C30B 29/68; C30B 29/02; C30B 29/52

(52) U.S. Cl. CPC G11B 5/738; C30B 23/08; C30B 23/025; G11B 2005/0021; C30B 29/02; C30B 29/52; C30B 29/68

(57) ABSTRACT

An apparatus includes a substrate, a plurality of layers overlying the substrate, a hexagonal close packed (hcp) translating layer, and an hcp layer overlying the hcp translating layer. A top layer of the multiple layers has a face centered cube (fcc) lattice structure. The hcp translating layer overlies the top layer. The hcp translating layer interfaces between the top layer and the hcp layer, and columnar structure of the top layer aligns with the hcp layer through the hcp translating layer.

### BACKGROUND

In magnetic recording media, as used in disk drive storage devices, information may be written to and read from magnetic elements, such as bits on a data storage disk. Such a data storage disk includes multiple layers. The multiple layers that are established perform many functions, such as storing information, directing growth during manufacturing, aiding in the writing and reading of the magnetic elements, etc.

A movable read/write head may perform read/write operations with the magnetic elements. The magnetic elements may be arranged in circular and concentric data tracks on the surface of one or more disks. Multiple data storage disks may be mounted in vertically spaced and parallel relation to one another on a hub that rotates about a shaft or sleeve of a motor.

### SUMMARY

Provided herein are techniques related to a translating layer enabling growth of face-centered-cubic (fcc) lattice structure on an hexagonal close packed (hcp) structure and vice versa. An apparatus includes a substrate, a plurality of layers overlying the substrate, an hcp translating layer, and an hcp layer overlying the hcp translating layer. A top layer of the multiple layers has a fcc lattice structure. The hcp translating layer overlies the top layer. The hcp translating layer interfaces between the top layer and the hcp layer, and columnar structure of the top layer aligns with the hcp layer through the hcp translating layer. These and other features and advantages will be apparent from a reading of the following detailed description.

### BRIEF DESCRIPTION OF THE DRAWINGS

The present disclosure is illustrated by way of example, and not by way of limitation, in the figures of the accompanying drawings and in which like reference numerals refer to similar elements.

FIGS. 1A-1B show a simplified cross-sectional view of a magnetic recording medium in accordance with some embodiments.

FIG. 2 is another simplified cross-sectional view of a magnetic recording medium, which may be used for the data storage disk in an embodiment.

FIG. 3 is a simplified cross-sectional view of a portion of the magnetic recording medium in accordance to another embodiment.

FIG. 4 is a flow diagram for creating a magnetic recording medium in accordance with one embodiment.

FIG. 5 is a plan view of a data storage device in which embodiments herein be implemented.

### DETAILED DESCRIPTION

Reference will now be made in detail to embodiments, examples of which are illustrated in the accompanying drawings. While the embodiments will be described in conjunction with the drawings, it will be understood that they are not intended to limit the embodiments. On the contrary, the embodiments are intended to cover alternatives, modifications and equivalents. Furthermore, in the following detailed description, numerous specific details are set forth in order to provide a thorough understanding. However, it will be recognized by one of ordinary skill in the art that the embodiments may be practiced without these specific details. In other instances, well-known methods, procedures, components, and circuits have not been described in detail as not to unnecessarily obscure aspects of the embodiments.

For expository purposes, the term “horizontal” as used herein refers to a plane parallel to the plane or surface of an object, regardless of its orientation. The term “vertical” refers to a direction perpendicular to the horizontal as just defined. Terms such as “above,” “below,” “bottom,” “top,” “side,” “higher,” “lower,” “upper,” “over,” and “under” are referred to with respect to the horizontal plane.

Remnant magnetization thickness ratio (Mrt) and performance of heat assisted media recording (HAMR) depend on the grain size. Unfortunately, growing the magnetic storage layer with small grains, e.g., smaller than 10 nm, with Mrt beyond 0.4-0.5 leads to increased roughness of the upper magnetic layer. Face cubic centered (fcc) lattice structures may be used to control smoothness and magnetic property, as well as protect the structure from corrosion and reduce the roughness. Unfortunately, using fcc lattice structures adversely impacts anisotropy and the curie temperature. On the other hand hexagonal close packed (hcp) lattice structures have high anisotropy and high curie temperature that is desirable. There has been no known method to achieve reduction in roughness, increased smoothness and magnetic properties using fcc lattice structures while achieving high anisotropy and high curie temperature of hcp lattice structures because growing an hcp lattice structure over an fcc lattice structure has not been feasible while achieving columnar alignment between the two.

Embodiments provided herein are directed to growing an hcp lattice structure over an fcc lattice structure while maintaining columnar alignment between the two structures. Embodiments provided herein, therefore, achieve the smoothness and magnetic property of the fcc lattice structure, protect the structure from corrosion, and result in reduction of roughness while having a high anisotropy and high curie temperature of an hcp lattice structure.

According to some embodiments, a thin layer of hcp lattice structure such as ZnO can be used as an interface between an fcc lattice structure such as FePt and an hcp lattice structure such as CoPtCrB that grows over the thin layer of hcp lattice structure. The thin layer of hcp lattice structure such as ZnO unexpectedly enables additional hcp layers such as CoPtCrB to be grown over the ZnO layer which overlies an fcc lattice structure while maintaining the columnar alignment between the hcp lattice structure and the fcc lattice structure. In other words, the thin layer of ZnO layer that interfaces between the fcc lattice structure and the hcp lattice structure changes the behavior of the hcp lattice structure (additional hcp layers) such that the columnar structure of the fcc lattice structure is aligned with that of the hcp lattice structure. In some embodiments, ZnO may be doped with Al, Ga, In, or a combination thereof to reduce resistivity. It is appreciated that doping ZnO may be through DC sputtering.

Magnetic recording media may include multiple layers. For example, magnetic recording media may include a disk substrate, soft underlayer, a seed layer, multiple interlayers, a magnetic recording layer, a protective overcoat layer, and a lubricant layer. In the case of HAMR media the layer stack typically also includes one or more heatsink layers, designed to confine and shape the heat profile emanating from the heat (light) source on the recording head. Each layer may be formed by different materials with different properties. For example, a layer may be amorphous (non-crystalline) or crystalline, may have a face-centered cubic, body-centered cubic (bcc) or hexagonal close-packed lattice structure, may be nonmagnetic, may be magnetic with out-of-plane (perpendicular) or in-plane (longitudinal) magnetic anisotropy, and so on. Specifically, in the case of HAMR media for the magnetic storage layer often a special case of fcc material, the so called-face-centered-tetragonal (FCT) or L1₀ phase of FePt and related materials may be used. The properties of each layer may affect the performance or writability, the manufacturing process, and the cost of manufacturing of the magnetic recording media.

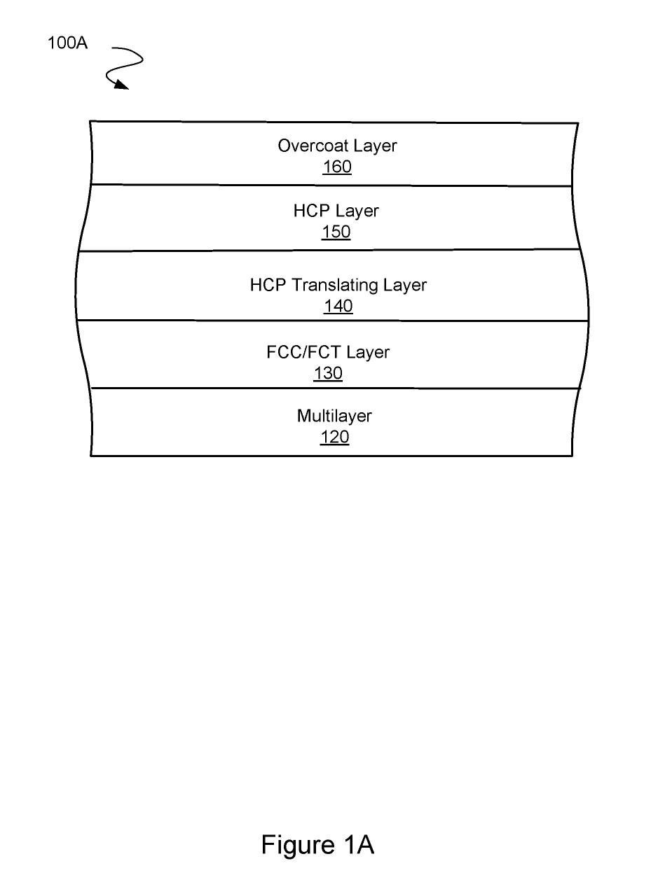

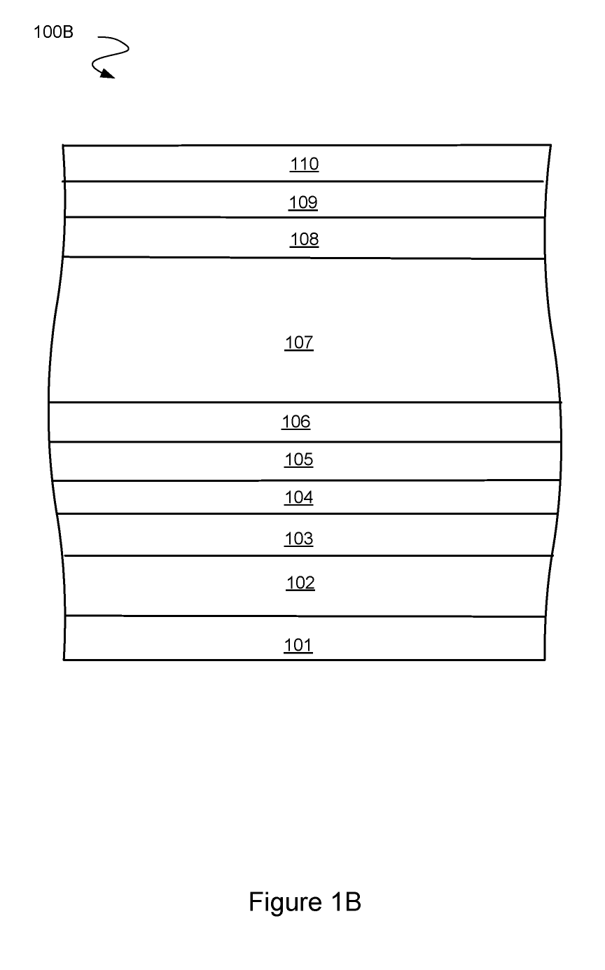

FIG. 1A shows a simplified cross-sectional view of a HAMR magnetic recording medium 100A. The magnetic recording medium 100A includes a multilayer 120, an fcc or face centered tetragonal (fct) magnetic storage layer 130, an hcp translating layer 140, an hcp layer 150, and an overcoat layer 160.

In some embodiments, the multilayer 120 may be a combination of amorphous layers and layers with fcc lattice structure. For example, the multilayer 120 may include a substrate, e.g., glass, followed by an amorphous soft magnetic underlayer, and then a fcc seed layer such as MgO (and/or its alloy), and a further fcc heatsink layer such as Ag, Cu, Au (and/or their alloys). The multilayer 120 may further include an fcc layer such as MgO on top.

In some embodiments, the multilayer 120 may be a combination of amorphous layers and layers with fcc lattice structure and hcp lattice structure. For example, the multilayer 120 may include a substrate, e.g., glass, followed by an amorphous soft magnetic underlayer, and then a fcc seed layer such as nickel (and/or its alloy), and an hcp layer such as ruthenium (and/or its alloy). The multilayer 120 may further include a translation layer such as ZnO that enables growth of fcc lattice structure on the hcp lattice structure. The translation layer may be grown to have a thickness of less than 2 nm. In some embodiments, ZnO may be doped with Al, Ga, In, or a combination thereof to reduce resistivity. It is appreciated that doping ZnO may be through DC sputtering. The multilayer 120 may further include an fcc layer such as MgO.

The fcc or fct magnetic storage layer 130 may include more than one layer. For example, the fcc layer 130 may include FeCuPt, FePt, or any combination thereof. It is appreciated that FeCuPt and FePt may be grown in [001] texture.

The hcp translating layer 140 is the layer that interfaces between the fcc lattice structure (as described above) with additional hcp layers over the hcp translating layer 140. The hcp translating layer 140 may be a thin layer that causes the hcp layer(s) that are deposited over the hcp translating layer 140 to have columnar structures that are aligned with the fcc lattice structure underneath. In some embodiments, the hcp translating layer 140 may be ZnO. It is appreciated that a ZnO alloy may also be used as the hcp translating layer 140. In some embodiments, ZnO may be doped with Al, Ga, In, or a combination thereof to reduce resistivity. It is appreciated that doping ZnO may be through DC sputtering. The translation layer 140 may be grown to have a thickness of less than 2 nm.

It is appreciated that one or more hcp layers 150 may be deposited over the hcp translating layer 140. For example, the hcp layer 150 may include CoPtCrB that is grown in [0001] texture. It is appreciated that the hcp layer 150 may also be referred to as a perpendicular magnetic recording (PMR) cap layer. In some embodiments, the hcp layer 150 is protected, e.g., reducing damage from read/write head interactions with the recording medium during start/stop operations, by depositing an overcoat layer 160. The overcoat layer 160 may be carbon layer and/or a lubricant layer.

It is appreciated that the hcp translating layer 140 enables two different lattice structure to be grown on top of one another while maintaining the columnar alignment. In this illustrative embodiment, the hcp translating layer 140 enables an hcp lattice structure of [0001] to be grown over and become aligned with an fcc lattice structure of [001]. As such, embodiments provided herein achieve the smoothness and magnetic property of the fcc lattice structure, protect the structure from corrosion, and result in roughness reduction while having a high anisotropy and high curie temperature of an hcp lattice structure.

Referring now to FIG. 1B, another simplified cross-sectional view of a magnetic recording medium 100B according to some embodiments is shown. The structure 100B includes a substrate 101, an adhesion layer 102, a soft underlayer 103, a seed layer 104, a heatsink layer 105, an interlayer 106, metal layers 107, an hcp translating layer 108, an hcp layer 109, and an overcoat layer 110.

The substrate 101 may be fabricated from aluminum (Al) coated with a layer of nickel phosphorous (NiP), glass and glass-containing materials including glass-ceramics, and ceramics including crystalline, partly crystalline, and amorphous ceramics, to name a few. The substrate 101 may have a smooth surface upon which the remaining layers may be deposited. It is appreciated that the adhesion layer 102 may be used to adhere subsequent layers to the substrate 101. For example, the adhesion layer 102 may be used to adhere the soft underlayer 103 to the substrate. The adhesion layer 102 may be established from elements such as Tantalum (Ta) and its alloys.

The soft underlayer 103 may be established from soft magnetic materials such as CoZrNb, CoZrTa, CoCrRu, FeCoB and FeTaC, to name a few. The soft underlayer 103 may be formed with a high permeability and a low coercivity according to one embodiment. It is appreciated that soft underlayer 103 materials having coercivity of 20-50 oersteds (Oe) may be considered as having high coercivity. In an embodiment the soft underlayer 103 may have a coercivity of not greater than about 10 Oe and a magnetic permeability of at least about 50. The soft underlayer 103 may comprise a single SUL or multiple soft underlayers. It is appreciated that spacers may be used to separate underlayers from one another if multiple soft underlayers are used. Moreover, it is appreciated that the soft underlayers may be fabricated from the same soft magnetic material or from different soft magnetic materials if multiple soft underlayers are used.

The seed layer 104 may be deposited over the soft underlayer 103. It is appreciated that the seed layer 104 may be magnetic and it may be strongly coupled to the soft underlayer 103. The thickness of the seed layer may be selected for proper crystallographic structure of subsequent layers as described above. The seed layer 104 may be formed, for example, by physical vapor deposition (PVD) or chemical vapor deposition (CVD). The use of these materials may result in optimized growth properties of magnetic recording islands (columnar structure), discussed below.

As discussed above, the material for the seed layer 104 is selected to have proper crystallographic structure for subsequent heatsink layer 105. For example, the seed layer 104 may include (i) a material with bcc lattice structure such as Cr and its alloys if the chosen heatsink 105 is bcc Cr, Mo, W, or Ta or (ii) a material with fcc lattice structure such as MgO and similar compounds if the selected heatsink 105 is fcc Cu, Ag or Au. The heatsink layer 105 may be deposited over the seed layer 104. In some embodiments, the heatsink layer 105 has an fcc lattice structure. In various embodiments, the heatsink layer 105 may be located between other layers of the magnetic recording medium 100B. In some embodiments, more than one heat sink layer may be located adjacent to each other and/or separated by other layers within the magnetic recording medium 100B.

The interlayer 106 may be deposited over the heatsink layer 105. The interlayer 106 may comprise one or more non-magnetic materials. It is appreciated that the interlayer 106 may serve to promote microstructural and magnetic properties of the hard recording layer in one embodiment. In some embodiments, the interlayer 106 may optimize media performance, e.g., by controlling the crystallographic orientation, grain size, grain distribution, etc. The interlayer 106 may also reduce exchange coupling between magnetically hard recording layers and magnetically soft layers.

Metal layers 107 may be deposited on the interlayer 106. It is appreciated that the metal layers 107 may include fcc or fct lattice type structure, e.g., FePt, FeCuPt, or other iron alloys, or any combination thereof. Using the fcc lattice type structure achieves the smoothness and magnetic property of the fcc lattice structure, protects the structure from corrosion, and results in roughness reduction. It is understood that the metal layers 107 is a non-limiting example, and various embodiments may include any number of metal layers (e.g., 1, 2, 3, . . . , 10 layers).

In order to achieve a high anisotropy and high curie temperature of an hcp lattice structure, the hcp translating layer 108 is deposited over the metal layers 107. The hcp translating layer 108 is the layer that interfaces between the fcc lattice structure (as described above) with additional hcp layers over the hcp translating layer 108. The hcp translating layer 108 may be a thin layer that causes the hcp layer(s) that are deposited over the hcp translating layer 108 to have columnar structures that are aligned with the fcc lattice structure underneath. In some embodiments, the hcp translating layer 108 may be ZnO. It is appreciated that a ZnO alloy may also be used as the hcp translating layer 108. In some embodiments, ZnO may be doped with Al, Ga, In, or a combination thereof to reduce resistivity. It is appreciated that doping ZnO may be through DC sputtering. The translation layer may be grown to have a thickness of less than 2 nm.

The hcp layer 109 is deposited over the hcp translating layer 108 and due to the hcp translating layer 108, columnar structure of the hcp layer 109 aligns with the columnar structure of the fcc layer, e.g., metal layers 107. For example, the hcp layer 109 may include CoPtCrB that is grown in [0001] texture. It is appreciated that the hcp layer 109 may also be referred to as a perpendicular magnetic recording (PMR) cap layer. In some embodiments, the hcp layer 109 is protected, e.g., reducing damage from read/write head interactions with the recording medium during start/stop operations, by depositing an overcoat layer 110. The overcoat layer 110 may be carbon layer or a lubricant layer.

It should be appreciated that embodiments described herein may be applied to other recording mediums as well, e.g., a longitudinal recording medium, bit-patterned media (BPM), discrete track recording (DTR), other non-magnetic recording mediums, or heat-assisted magnetic recording (HAMR).

It is appreciated that the hcp translating hcp layer 108 enables two different lattice structures to be grown on top of one another while maintaining the columnar alignment. In this illustrative embodiment, the hcp translating layer 108fc enables an hcp lattice structure of [0001] to be grown over and become aligned with an fcc lattice structure of [001]. As such, embodiments provided herein achieve the smoothness and magnetic property of the fcc lattice structure, protect the structure from corrosion, and result in roughness reduction while having a high anisotropy and high curie temperature of an hcp lattice structure.

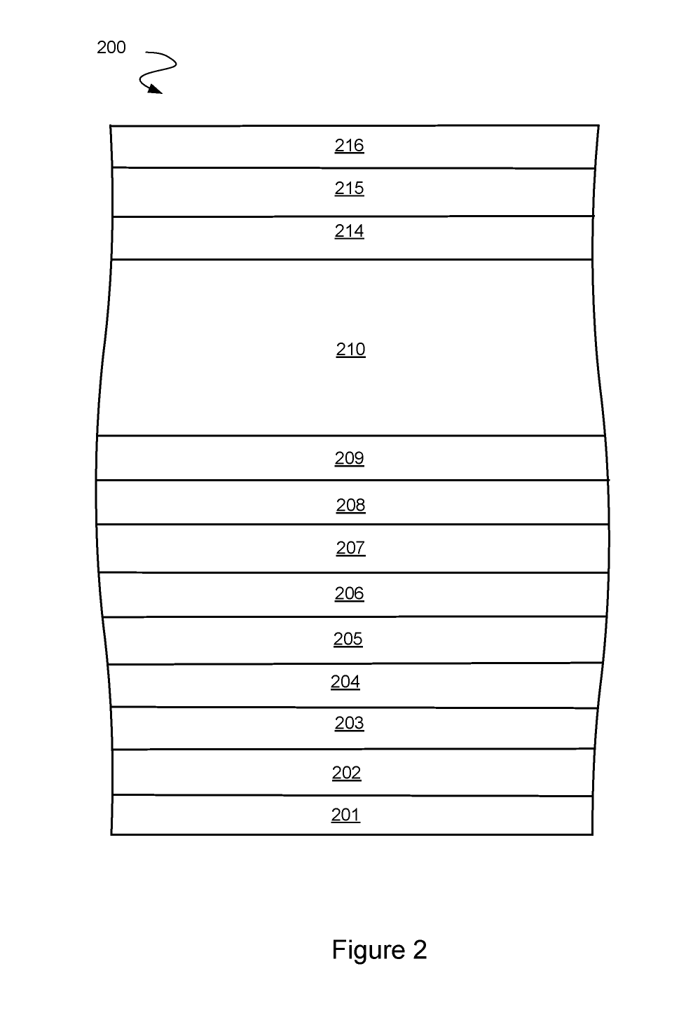

Referring now to FIG. 2, a simplified cross-sectional view of a magnetic recording medium 200 according to some embodiments is shown. The structure 200 includes a substrate 201, a soft underlayer 202, a seed layer 203, multilayered heatsink layers 204-206, an interlayer 207, an fcc translating layer 208, an fcc layer 209, multilayer fcc layers 210, an hcp translating layer 214, an hcp layer 215, and an overcoat 216.

The substrate 201 may be fabricated from aluminum (Al) coated with a layer of nickel phosphorous (NiP), glass and glass-containing materials including glass-ceramics, and ceramics including crystalline, partly crystalline, and amorphous ceramics, to name a few. The substrate 201 may have a smooth surface upon which the remaining layers may be deposited. It is appreciated that the soft underlayer 202 may be deposited on the substrate 201. The soft underlayer 202 may be established from soft magnetic materials such as CoZrNb, CoZrTa, CoCrRu, FeCoB and FeTaC, to name a few. In some embodiments, the soft underlayer 202 may be formed from a chromium material or an alloy thereof. The soft underlayer 202 may be formed with a high permeability and a low coercivity according to one embodiment. It is appreciated that soft underlayer 103 materials having coercivity of 20-50 oersteds (Oe) may be considered as having high coercivity. In an embodiment the soft underlayer 202 may have a coercivity of not greater than about 10 Oe and a magnetic permeability of at least about 50. The soft underlayer 202 may comprise a single SUL or multiple soft underlayers. It is appreciated that spacers may be used to separate underlayers from one another if multiple soft underlayers are used. Moreover, it is appreciated that the soft underlayers may be fabricated from the same soft magnetic material or from different soft magnetic materials if multiple soft underlayers are used. In some embodiments, the soft underlayer 202 may be grown to a 15 nm thickness.

The seed layer 203 may be deposited over the soft underlayer 202. For example in one embodiment, a 100 Å or less seed layer 203 may be grown directly on the soft underlayer 202. The seed layer 104 may be formed, for example, by physical vapor deposition (PVD) or chemical vapor deposition (CVD). The use of these materials may result in optimized growth properties of magnetic recording islands (columnar structure), discussed below.

Seed layer 203 may include a material with fcc lattice, such as Ni and its alloys. The seed layer 203 may be grown to a thickness of 2 nm to 10 nm.

The multilayered heatsink layers 204-206 may be deposited over the seed layer 203. In some embodiments, the heatsink layer 105 may be an hcp lattice structure and it may include ruthenium (Ru) or an alloy thereof. In some embodiments, the heatsink layer 204 includes a RuCoCr and it is grown to 2 nm, the heatsink layer 205 includes Ru and it is grown to 50 nm, and the heatsink layer 206 includes Ru—TiO2 and it is grown between 1-2 nm. It is appreciated that the number of layers and their thicknesses described are for illustrative purposes and not intended to limit the scope of the embodiments. For example, more than 3 heatsink layers may be used with varying thicknesses than the ones described above. In various embodiments, the heatsink layer 204-206 may be located between other layers of the magnetic recording medium. In some embodiments, more than one heat sink layer may be located adjacent to each other and/or separated by other layers within the magnetic recording medium.

The interlayer 207 may be deposited over the heatsink layers 204-206. The interlayer 207 may comprise one or more non-magnetic materials that may serve to reduce or substantially prevent magnetic interactions between the soft underlayer 202 and the seed layer 203 in accordance with one embodiment. It is appreciated that the interlayer 207 may serve to promote microstructural and magnetic properties of the hard recording layer in one embodiment. In some embodiments, the interlayer 207 may optimize media performance, e.g., by controlling the crystallographic orientation, grain size, grain distribution, etc. The interlayer 207 may also reduce exchange coupling between magnetically hard recording layers and magnetically soft layers. It is appreciated that the interlayer 207 may provide physical separation between adjacent grains in one embodiment. The interlayer 207 may include Pt—TiO2 and it may be grown to approximately 2 nm.

In some embodiments, it may be advantageous to grow an fcc lattice structure over the underlying hcp lattice structure. As such, the fcc translating layer 208 may be used. The fcc translating layer 208 may be a thin layer, e.g., 2 nm, that once deposited over the hcp lattice structure, enables fcc layers to be deposited while adhering to the columnar structure alignment of the underlying hcp lattice structure. The fcc translating layer 208 may include ZnO. In some embodiments, ZnO may be doped with Al, Ga, In, or a combination thereof to reduce resistivity. It is appreciated that doping ZnO may be through DC sputtering. The translation layer may be grown to have a thickness of less than 2 nm.

The fcc layer 209 may be deposited over the fcc translating layer 208. The fcc layer 209 may include MgO and it may be grown to a thickness of 5 nm.

Additional fcc layers 210 may be deposited on the fcc layer 209. It is appreciated that the additional fcc layers 210 may include fcc lattice type structure, e.g., FePt, FeCuPt, or other iron alloys, or any combination thereof. Using the fcc lattice type structure achieves the smoothness and magnetic property of the fcc lattice structure, protects the structure from corrosion, and results in roughness reduction. However, in order to achieve a high anisotropy and high curie temperature of an hcp lattice structure, the hcp translating layer 214 is deposited over the additional fcc layers 210.

The hcp translating layer 214 is the layer that interfaces between the fcc lattice structure (as described above) with additional hcp layers over the hcp translating layer 214. The hcp translating layer 214 may be a thin layer, e.g., 1-2 nm in thickness, that causes the hcp layer(s) that are deposited over the hcp translating layer 214 to have columnar structures that are aligned with the fcc lattice structure underneath. In some embodiments, the hcp translating layer 214 may be ZnO. It is appreciated that a ZnO alloy may also be used as the hcp translating layer 214. In some embodiments, ZnO may be doped with Al, Ga, In, or a combination thereof to reduce resistivity. It is appreciated that doping ZnO may be through DC sputtering. The translation layer may be grown to have a thickness of less than 2 nm.

The hcp layer 215 is deposited over the hcp translating layer 214 and due to the hcp translating layer 214, columnar structure of the hcp layer 215 aligns with the columnar structure of the fcc layer, e.g., fcc layers 210. For example, the hcp layer 215 may include CoPtCrB that is grown in [0001] texture and it may be grown between 2-5 nm in thickness. It is appreciated that the hcp layer 215 may also be referred to as a perpendicular magnetic recording (PMR) cap layer. In some embodiments, the hcp layer 215 is protected, e.g., reducing damage from read/write head interactions with the recording medium during start/stop operations, by depositing an overcoat layer 216. The overcoat layer 216 may be carbon layer and/or a lubricant layer.

It should be appreciated that embodiments described herein may be applied to other recording mediums as well, e.g., a longitudinal recording medium, bit-patterned media (BPM), discrete track recording (DTR), other non-magnetic recording mediums, or heat-assisted magnetic recording (HAMR).

It is appreciated that the fcc and hcp translating layers 208 and 214 enable growth of fcc lattice structure on an hcp lattice structure and vice versa while maintaining the columnar alignment. In this illustrative embodiment, the hcp translating layer 214 enables an hcp lattice structure of [0001] to be grown over and become aligned with an fcc lattice structure of [001]. In this illustrative embodiment, the fcc translating layer 208 enables an fcc lattice structure of [001] to be grown over and become aligned with an hcp lattice structure of [0001]. As such, embodiments provided herein achieve the smoothness and magnetic property of the fcc lattice structure, protect the structure from corrosion, and result in roughness reduction while having a high anisotropy and high curie temperature of an hcp lattice structure.

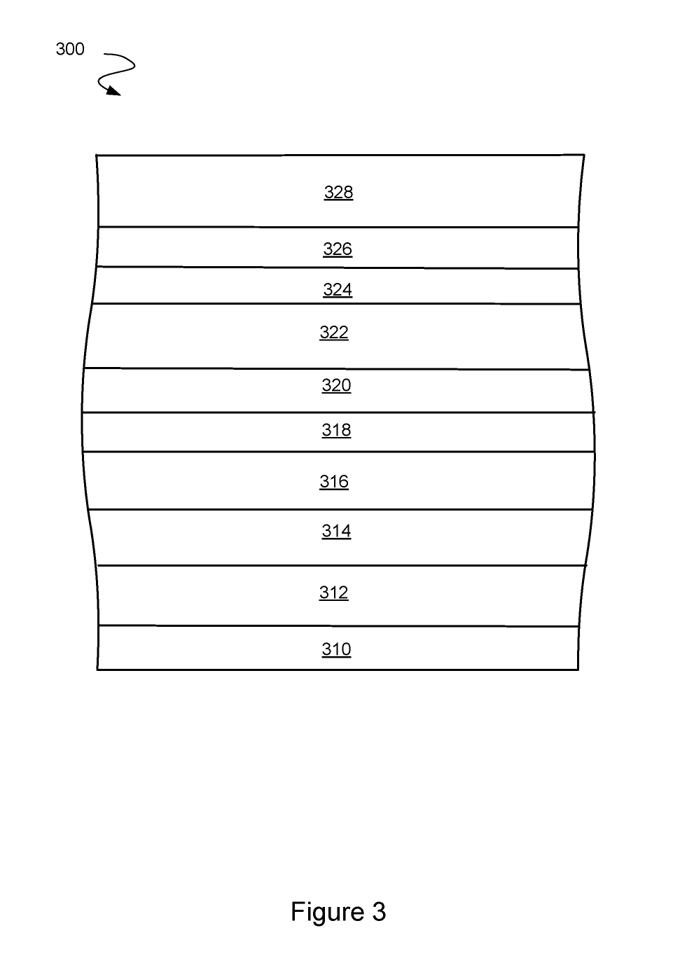

Referring now to FIG. 3, another simplified cross-sectional view of a magnetic recording medium 300 according to some embodiments is shown. The structure 300 includes a substrate 310, an adhesion layer 312, a soft underlayer 314, a heatsink layer 316, an fcc layer 318, an fcc multilayer 320-322, an hcp translating layer 324, an hcp layer 326, and an overcoat layer 328.

The substrate 310 may be fabricated from aluminum (Al) coated with a layer of nickel phosphorous (NiP), glass and glass-containing materials including glass-ceramics, and ceramics including crystalline, partly crystalline, and amorphous ceramics, to name a few. The substrate 310 may have a smooth surface upon which the remaining layers may be deposited. It is appreciated that the adhesion layer 312 may be used to adhere subsequent layers to the substrate 310 and it may comprise aluminum. For example, the adhesion layer 312 may be used to adhere the soft underlayer 314 to the substrate 310. In some embodiments, the adhesion layer 312 may be established from elements such as Tantalum (Ta).

The soft underlayer 314 may be established from soft magnetic materials such as CoZrNb, CoZrTa, CoCrRu, FeCoB and FeTaC, to name a few. The soft underlayer 314 may be formed with a high permeability and a low coercivity according to one embodiment. It is appreciated that soft underlayer 314 materials having coercivity of 20-50 oersteds (Oe) may be considered as having high coercivity. In an embodiment the soft underlayer 314 may have a coercivity of not greater than about 10 Oe and a magnetic permeability of at least about 50. The soft underlayer 314 may comprise a single SUL or multiple soft underlayers. It is appreciated that spacers may be used to separate underlayers from one another if multiple soft underlayers are used. Moreover, it is appreciated that the soft underlayers may be fabricated from the same soft magnetic material or from different soft magnetic materials if multiple soft underlayers are used.

The heatsink layer 316 may be deposited over the soft underlayer 314. The heatsink layer 316 may be formed of an fcc lattice structure. It is appreciated that the fcc layer 318 may be deposited over the heatsink layer 316. The fcc layer 318 may include MgO in some embodiments. In various embodiments, the heatsink layer 316 may be located between other layers of the magnetic recording medium. In some embodiments, more than one heat sink layer may be located adjacent to each other and/or separated by other layers within the magnetic recording medium.

In some embodiments, fcc multilayers 320-322 are deposited over the fcc layer 318. The fcc multilayers 320-322 have fcc lattice structure. For example, the fcc layer 320 may include FeCuPt and the fcc layer 322 may include FePt. It is appreciated that other iron alloys may be used and the use of two layers and the two alloys is exemplary and not intended to limit the scope of the embodiments.

Using the fcc lattice type structure achieves the smoothness and magnetic property of the fcc lattice structure, protects the structure from corrosion, and results in roughness reduction. However, in order to achieve a high anisotropy and high curie temperature of an hcp lattice structure, the hcp translating layer 324 is deposited over the fcc multilayers 320-322. The hcp translating layer 324 is the layer that interfaces between the fcc lattice structure (as described above) with additional hcp layers over the hcp translating layer 324. The hcp translating layer 324 may be a thin layer that causes the hcp layer(s) that are deposited over the hcp translating layer 324 to have columnar structures that are aligned with the fcc lattice structure underneath. In some embodiments, the hcp translating layer 324 may be ZnO. It is appreciated that a ZnO alloy may also be used as the hcp translating layer 324. In some embodiments, ZnO may be doped with Al, Ga, In, or a combination thereof to reduce resistivity. It is appreciated that doping ZnO may be through DC sputtering. The translation layer may be grown to have a thickness of less than 2 nm.

The hcp layer 326 is deposited over the hcp translating layer 324 and due to the hcp translating layer 324, columnar structure of the hcp layer 326 aligns with the columnar structure of the fcc layer, e.g., fcc multilayers 320-322. For example, the hcp layer 326 may include CoPtCrB that is grown in [0001] texture. It is appreciated that the hcp layer 326 may also be referred to as a perpendicular magnetic recording (PMR) cap layer. In some embodiments, the hcp layer 326 is protected, e.g., reducing damage from read/write head interactions with the recording medium during start/stop operations, by depositing an overcoat layer 328. The overcoat layer 328 may be carbon layer or a lubricant layer.

It should be appreciated that embodiments described herein may be applied to other recording mediums as well, e.g., a longitudinal recording medium, bit-patterned media (BPM), discrete track recording (DTR), other non-magnetic recording mediums, or heat-assisted magnetic recording (HAMR).

It is appreciated that the hcp translating hcp layer 324 enables two different lattice structure to be grown on top of one another while maintaining the columnar alignment. In this illustrative embodiment, the hcp translating layer 324 enables an hcp lattice structure of [0001] to be grown over and become aligned with an fcc lattice structure of [001]. As such, embodiments provided herein achieve the smoothness and magnetic property of the fcc lattice structure, protect the structure from corrosion, and result in roughness reduction while having a high anisotropy and high curie temperature of an hcp lattice structure.

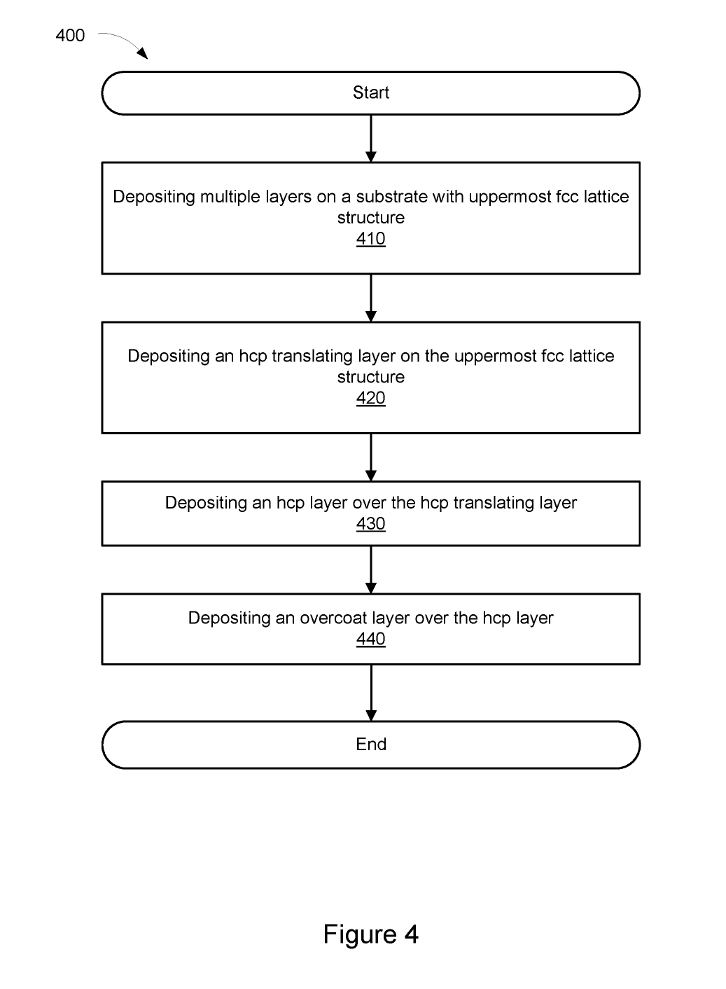

FIG. 4 depicts a flowchart 400 of an exemplary process of creating a storage medium structure, according to an embodiment. At step 410, multiple layers are deposited on a substrate where their uppermost layer has an fcc lattice structure. For example as shown in FIGS. 1A-1B, 2, and 3, any combination of layers adhesion layer, soft underlayer, seed layer, heatsink layer(s), interlayer, etc. may be deposited over the substrate. It is appreciated that deposition of multiple layers on the substrate may include chromium alloy, aluminum, nickel or its alloy, RuCoCr, Ru, Ru—TiO2, Pt—TiO2, MgO, FeCuPt, FePt, etc. It is appreciated that the layers may include hcp layer, an fcc translation layer, followed by an fcc lattice structure as its uppermost layer, as discussed with respect to FIGS. 1A and 2. It is appreciated that deposition of multiple layers at step 410 may include all fcc lattice structure layers, in some embodiments.

At step 420, an hcp translating layer is deposited on the uppermost fcc lattice structure. For example, the hcp translating layer may be similar to the layer 140 in FIG. 1A, layer 108 in FIG. 1B, layer 214 in FIG. 2, and layer 324 in FIG. 3. Depositing the hcp translating layer enables hcp lattice structure to grow on an fcc lattice structure while maintaining the columnar structure alignment of the fcc lattice structure. At step 430, an hcp layer is deposited over the hcp translating layer. The hcp layer deposited over the hcp translating layer may be similar to layer 150 of FIG. 1A, layer 109 of FIG. 1B, layer 215 of FIG. 2, and layer 326 of FIG. 3. In one optional embodiment, at step 440, an overcoat is deposited over the hcp layer. The overcoat layer is similar to the overcoat layer as described in FIGS. 1A-1B, 2, and 3.

It is appreciated that the hcp translating hcp layer enables two different lattice structure to be grown on top of one another while maintaining the columnar alignment. In this illustrative embodiment, the hcp translating layer enables an hcp lattice structure of [0001] to be grown over and become aligned with an fcc lattice structure of [001]. As such, embodiments provided herein achieve the smoothness and magnetic property of the fcc lattice structure, protect the structure from corrosion, and result in roughness reduction while having a high anisotropy and high curie temperature of an hcp lattice structure.

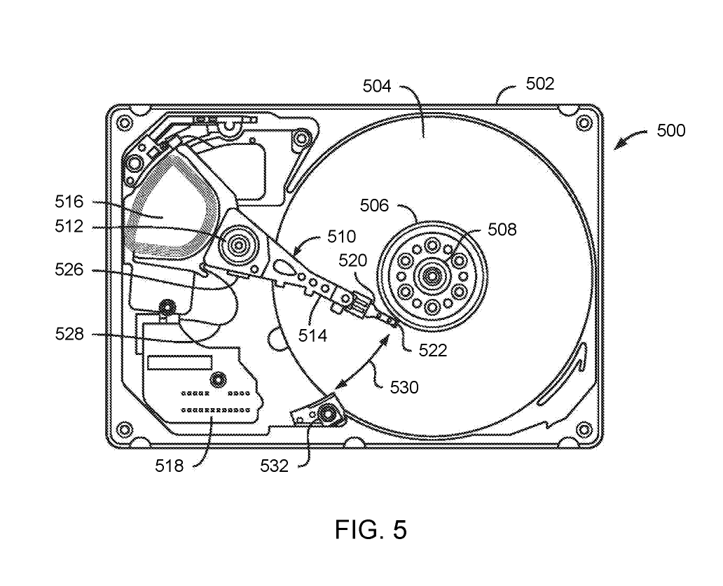

FIG. 5 is a plan view of a data storage device in which embodiments herein may be implemented. A disk drive 500 generally includes a base plate 502 and a cover (not shown) that may be disposed on the base plate 502 to define an enclosed housing for various disk drive components. The disk drive 500 includes one or more disk substrates or data storage disks 504 of computer-readable data storage media. Typically, both of the major surfaces of each data storage disk 504 include a plurality of concentrically disposed tracks for storing data. Each data storage disk 504 is mounted on a hub or spindle 506, which in turn is rotatably interconnected with the base plate 502 and/or cover. Multiple data storage disks 504 are typically mounted in vertically spaced and parallel relation with respect to one another on the spindle 506. A spindle motor 508 rotates the data storage disks 504.

The disk drive 500 also includes an actuator arm assembly 510 that pivots about a pivot bearing 512, which in turn is rotatably supported by the base plate 502 and/or cover. The actuator arm assembly 510 includes one or more individual rigid actuator arms 514 that extend out from near the pivot bearing 512. Multiple actuator arms 514 are typically disposed in vertically spaced relation, with one actuator arm 514 being provided for each major data storage surface of each data storage disk 504 of the disk drive 500. Other types of actuator arm assembly configurations could be utilized as well, e.g., an “E” block having one or more rigid actuator arm tips or the like that cantilever from a common structure. Movement of the actuator arm assembly 510 is provided by an actuator arm drive assembly, such as a voice coil motor 516 or the like. The voice coil motor 516 is a magnetic assembly that controls the operation of the actuator arm assembly 510 under the direction of control electronics 518.

A load beam or suspension 520 is attached to the free end of each actuator arm 514 and cantilevers therefrom. Typically, the suspension 520 is biased generally toward its corresponding data storage disk 504 by a spring-like force. A slider 522 is disposed at or near the free end of each suspension 520. What is commonly referred to as the read/write head (e.g., transducer) is appropriately mounted as a head unit (not shown) under the slider 522 and is used in disk drive read/write operations. The head unit under the slider 522 may utilize various types of read sensor technologies such as anisotropic magnetoresistive (AMR), giant magnetoresistive (GMR), tunneling magnetoresistive (TuMR), other magnetoresistive technologies, or other suitable technologies.

The head unit under the slider 522 is connected to a preamplifier 526, which is interconnected with the control electronics 518 of the disk drive 500 by a flex cable 528 that is typically mounted on the actuator arm assembly 510. Signals are exchanged between the head unit and its corresponding data storage disk 504 for disk drive read/write operations. In this regard, the voice coil motor 516 is utilized to pivot the actuator arm assembly 510 to simultaneously move the slider 522 along a path 530 and across the corresponding data storage disk 504 to position the head unit at the appropriate position on the data storage disk 504 for disk drive read/write operations.

When the disk drive 500 is not in operation, the actuator arm assembly 510 is pivoted to a “parked position” to dispose each slider 522 generally at or beyond a perimeter of its corresponding data storage disk 504, but in any case in vertically spaced relation to its corresponding data storage disk 504. In this regard, the disk drive 500 includes a ramp assembly 532 that is disposed beyond a perimeter of the data storage disk 504 to both move the corresponding slider 522 vertically away from its corresponding data storage disk 504 and to also exert somewhat of a retaining force on the actuator arm assembly 510.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings.

What is claimed is:

1. An apparatus comprising:
a substrate;
a plurality of layers overlying the substrate, wherein a top layer of the plurality of layers has a face centered cube (fcc) lattice structure;
a hexagonal close packed (hcp) translating layer overlying the top layer; and
an hcp layer overlaying the hcp translating layer, wherein the hcp translating layer interfaces between the top layer and the hcp layer, and wherein columnar structure of the top layer aligns with the hcp layer through the hcp translating layer.

2. The apparatus of claim 1, wherein the plurality of layers comprises:
an hcp lattice structure; and
an fcc translating layer overlaying a top layer of the hcp lattice structure, wherein the fcc translating layer interfaces between the top layer and the hcp lattice structure, and wherein columnar structure of the hcp lattice structure aligns with the top layer through the fcc translating layer.

3. The apparatus of claim 2, wherein the fcc translating layer comprises ZnO.

4. The apparatus of claim 3, wherein the ZnO is doped to reduce its resistivity.

5. The apparatus of claim 3, wherein the doping material is selected from a group consisting of Al, Ga, and In.

6. The apparatus of claim 2, wherein the hcp lattice structure comprises Ru.

7. The apparatus of claim 1, wherein the hcp translating layer comprises ZnO.

8. The apparatus of claim 7, wherein the ZnO is doped to reduce its resistivity.

9. The apparatus of claim 8, wherein the doping material is selected from a group consisting of Al, Ga, and In.

10. The apparatus of claim 1, wherein the hcp translating layer is less than 2 nm in thickness.

11. The apparatus of claim 1, wherein the hcp layer comprises CoPtCrB.

12. The apparatus of claim 11, wherein CoPtCrB is between 2-5 nm in thickness.

13. The apparatus of claim 1 further comprising:
an overcoat layer overlaying the hcp layer, wherein the overcoat layer reduces damage from read/write head interactions with recording medium during start/stop operations.

14. The apparatus of claim 1, wherein the top layer is selected from a group consisting of FePt and FeCuPt.

15. An apparatus comprising:
a substrate;
an face centered cube (fcc) lattice structure disposed over the substrate;
a hexagonal close packed (hcp) translating layer overlying the fcc lattice structure; and
an hcp layer overlaying the hcp translating, wherein the hcp translating layer interfaces between the fcc lattice structure and the hcp layer, and wherein columnar structure of the fcc lattice structure aligns with the hcp layer through the hcp translating layer.

16. The apparatus of claim 15, wherein the hcp translating layer comprises ZnO.

17. The apparatus of claim 16, wherein the ZnO is doped to reduce its resistivity.

18. The apparatus of claim 17, wherein the doping material is selected from a group consisting of Al, Ga, and In.

19. The apparatus of claim 15, wherein the hcp translating layer is less than 2 nm in thickness.

20. The apparatus of claim 15, wherein the hcp layer comprises CoPtCrB.

21. The apparatus of claim 20, wherein CoPtCrB is between 2-5 nm in thickness.

22. The apparatus of claim 15 further comprising:
an overcoat layer overlaying the hcp layer, wherein the overcoat layer reduces damage from read/write head interactions with recording medium during start/stop operations.

23. The apparatus of claim 15, wherein the fcc lattice structure is selected from a group consisting of FePt and FeCuPt.

24. An apparatus comprising:
a substrate;
a hexagonal packed (hcp) lattice structure overlying the substrate;
an face centered cube (fcc) translating layer overlaying the hcp lattice structure,
an fcc layer overlaying the fcc translating layer, wherein the fcc translating layer interfaces between the hcp lattice structure and the fcc layer, and wherein columnar structure of the hcp lattice structure aligns with the fcc layer through the fcc translating layer;
an hcp translating layer overlying the fcc layer; and
an hcp layer overlaying the hcp translating, wherein the hcp translating layer interfaces between the fcc layer and the hcp layer, and wherein columnar structure of the fcc layer aligns with the hcp layer through the hcp translating layer.

25. The apparatus of claim 24, wherein the fcc translating layer and the hcp translating layer each comprises ZnO.

26. The apparatus of claim 25, wherein the ZnO is doped to reduce its resistivity.

27. The apparatus of claim 26, wherein the doping material is selected from a group consisting of Al, Ga, and In.

28. The apparatus of claim 24, wherein the hcp lattice structure comprises Ru.

29. The apparatus of claim 24, wherein the hcp translating layer and the fcc translating layer is each less than 2 nm in thickness.

30. The apparatus of claim 24, wherein the hcp layer comprises CoPtCrB.

31. The apparatus of claim 30, wherein CoPtCrB is between 2-5 nm in thickness.

32. The apparatus of claim 24, wherein the fcc lattice structure is selected from a group consisting of FePt and FeCuPt.
